(19) United States
(12) Patent Application Publication
(10) Pub. No.: US 2026/0291166 A1
(43) Pub. Date: Sep. 24, 2026

(54) OPTOELECTRONIC SEMICONDUCTOR COMPONENT AND PRODUCTION METHOD

(71) Applicant: ams-OSRAM International GmbH, Regensburg (DE)

(72) Inventors: Jan MARFELD, Regensburg (DE); Nicole BERNER, Walderbach (DE); Erik HEINEMANN, Regensburg (DE); Andreas FRÖHLICH, Regensburg (DE)

(73) Assignee: ams-OSRAM International GmbH, Regensburg (DE)

(21) Appl. No.: 19/476,444

(22) PCT Filed: Apr. 8, 2024
(86) PCT No.: PCT/EP2024/059465

§ 371 Date: Oct. 17, 2025

(30) Foreign Application Priority Data
Apr. 21, 2023 (DE) 102023110176.5

(51) Int. Cl. H01S 5/0233; G02B 27/01

(52) U.S. Cl. CPC H01S 5/0233; G02B 27/0172; G02B 2027/0178

(57) ABSTRACT

In at least one embodiment, the optoelectronic semiconductor component includes an IC chip based on a semiconductor material, said IC chip having an upper face, and at least one optoelectronic semiconductor chip, wherein the at least one optoelectronic semiconductor chip is fitted completely in at least one cavity of the IC chip, the at least one cavity goes out from the upper face, and the at least one optoelectronic semiconductor chip is electrically connected directly to the IC chip.

### CROSS-REFERENCE TO RELATED APPLICATIONS

The present application is a national stage entry from International Application No. PCT/EP2024/059465, filed on Apr. 8, 2024, published as International Publication No. WO 2024/217910 A1 on Oct. 24, 2024, and claims priority to German Patent Application No. 10 2023 110 176.5, filed Apr. 21, 2023, the disclosures of all of which are hereby incorporated by reference in their entireties.

### FIELD

An optoelectronic semiconductor device is provided. In addition, a manufacturing method for such an optoelectronic semiconductor device is provided.

### BACKGROUND

An object to be achieved is to provide an optoelectronic semiconductor device that can be switched efficiently.

This object is solved, inter alia, by an optoelectronic semiconductor device and by a manufacturing method having the features of the independent patent claims. Preferred further embodiments are the subject of the dependent claims.

### SUMMARY

According to at least one embodiment, the optoelectronic semiconductor device comprises an IC chip having a top side. The top side may be a main side of the IC chip. The IC chip is based on at least one semiconductor material, such as silicon, or Si for short. IC stands for integrated circuit.

According to at least one embodiment, the IC chip comprises several transistors, such as metal-oxide-semiconductor field-effect transistors, or MOSFETs for short. The IC chip may also comprise other electronic components, such as electrical resistors. Optionally, the IC chip has at least one coil and/or one capacitor, but preferably the IC chip only comprises transistors and optionally electrical resistors. The number of transistors in the IC chip can be comparatively small and can, for example, be at least two or at least four and alternatively or additionally at most 104 or at most 103 or at most 102. The IC chip can be constructed in digital-to-analog converter architecture.

According to at least one embodiment, the optoelectronic semiconductor device comprises one or more optoelectronic semiconductor chips. The at least one optoelectronic semiconductor chip is preferably configured to generate and emit radiation during operation. The radiation is, for example, near-ultraviolet radiation, visible light and/or near-infrared radiation. If several of the optoelectronic semiconductor chips are present, different types of optoelectronic semiconductor chips may be combined. For example, red, green and blue emitting optoelectronic semiconductor chips may be present, which may in particular be electrically operable independently of one another, also referred to as an RGB module.

The IC chip can be a driver chip. It is possible that the IC chip comprises a maximum of 32 or a maximum of eight or a maximum of four or two or one driver channel. In other words, the IC chip is then configured to drive a relatively small number of optoelectronic semiconductor chips and/or semiconductor lasers. An optoelectronic semiconductor chip can comprise several semiconductor lasers, for example, ridge waveguide lasers, each of which can be individually assigned to one of the driver channels.

According to at least one embodiment, the at least one optoelectronic semiconductor chip is predominantly or completely located in one or more cavities of the IC chip. Predominantly means, for example, that at least 80% or at least 90% or at least 95% of a volume of the optoelectronic semiconductor chip in question is located in the associated cavity. In the cavity means, for example, a volume that lies between a semiconductor material of the IC chip and shortest connecting lines between opposing points of edges of the cavity.

If the semiconductor device comprises several of the optoelectronic semiconductor chips and several of the cavities, there may be several of the optoelectronic semiconductor chips per cavity; alternatively, there may be exactly one semiconductor chip per cavity, whereby combinations of these are possible.

According to at least one embodiment, the at least one cavity extends from the top side. In other words, at least one hole or trench or cut-out is formed in the top side. In areas adjacent to the at least one cavity, the top side may be flat.

According to at least one embodiment, the at least one optoelectronic semiconductor chip is electrically connected directly to the IC chip.

This means, for example, that there are no other interposed active or passive electrical components, such as resistors, inductors or capacitors, between the IC chip and the at least one optoelectronic semiconductor chip. For example, an electrical resistance, such as of an electrical connection, between the at least one optoelectronic semiconductor chip and the IC chip is at most 5Ω or at most 0.5Ω.

In at least one embodiment, the optoelectronic semiconductor device comprises:
an IC chip based on a semiconductor material and having a top side, and
at least one optoelectronic semiconductor chip, wherein
the at least one optoelectronic semiconductor chip is predominantly or completely mounted in at least one cavity of the IC chip,
the at least one cavity extends from the top side, and
the at least one optoelectronic semiconductor chip is electrically connected directly to the IC chip;
optionally, the at least one cavity is open towards the top side of the IC chip and towards exactly one side face of the IC chip.

For example, the optoelectronic semiconductor device is a compact laser module with an integrated driver. It is also possible to integrate an IC chip with LED chips.

In the optoelectronic semiconductor device described herein, a driver IC is designed as part of the package and thus fully integrated into the latter. The cavity in the driver IC allows the integration of laser diode chips as lateral emitters, also known as side lookers. Stacking several ICs with associated laser diodes enables a compact design for several laser diode channels. Other optoelectronic components, such as sensors or light-emitting diodes, can also be used instead of or in addition to laser diodes.

The integration of an IC usually makes a package larger, as the at least one optoelectronic semiconductor chip and the IC chip are mounted on the same level of a substrate. If a hermetic package is required, for example for LED chips that emit ultraviolet radiation or for packages that are to be used in very harsh environmental conditions, the larger component dimensions make it more difficult to manufacture the hermetic cavity.

In the optoelectronic semiconductor device described herein, the laser chip and IC chip are connected directly, in particular without an additional carrier substrate. The IC chip can therefore be used as an enclosure or, with an additional glass, as a hermetic housing. No additional substrates are required for rewiring. LED chips can be mounted directly in the cavity on the IC chip. Thus, the IC chip is also used as part of the package.

This design makes it possible to shorten wiring paths, which has a positive effect on the switching times that can be achieved. The IC chip can be used as an enclosure or with an additional glass as a hermetic housing.

As an alternative to a cover glass, the cavity can also be potted with a suitable material, such as an epoxy, a silicone or a siloxane, whereby optical filter materials can also be used. The at least one cavity in the IC chip thus creates a mounting surface for the optoelectronic semiconductor chips, which can then be closed by a cover glass or alternatively potted.

This makes it possible to achieve a compact design, very short switching times and very small optical coupling areas. In addition, a high packing density of several laser diodes is possible. Overall, fewer separate components are required. Lower manufacturing costs can be achieved, in particular through the use of processes still in the wafer composite. There is great flexibility in the electrical interconnection. A high degree of integration is possible. Hermetically sealed packages can be designed, whereby the IC chip can be used as part of the package.

According to at least one embodiment, the optoelectronic semiconductor device comprises a plurality of the optoelectronic semiconductor chips. For example, the number of optoelectronic semiconductor chips is at least two or at least three. Alternatively or additionally, this number is at most 64 or at most 16 or at most eight.

According to at least one embodiment, the IC chip comprises a silicon base body. This means, for example, that a mechanically carrier component of the IC chip is silicon. The term silicon base body does not exclude the presence of metal layers and electrical isolation layers with which the electrical components of the IC chip, such as transistors and electrical conductors, are designed.

According to at least one embodiment, the at least one cavity is located in the silicon base body. That is, the at least one cavity is not only superficial, but extends into the silicon base body. A depth of the at least one cavity is, for example, at least 10% or at least 20% or at least 30% and/or at most 80% or at most 70% or at most 60% of a thickness of the silicon base body and/or the IC chip.

According to at least one embodiment, the optoelectronic semiconductor device comprises at least one further IC chip with at least one further cavity and with a further top side. With regard to the design of the further IC chip, the further cavity and the further top side, the description of the IC chip applies accordingly. For example, between one and five of the further IC chips are present.

According to at least one embodiment, one or more of the optoelectronic semiconductor chips is predominantly or completely located in the at least one further cavity. It is possible that all optoelectronic semiconductor chips that are not assigned to the at least one cavity of the IC chip are assigned to the at least one further cavity of the at least one further IC chip.

According to at least one embodiment, the IC chip and the at least one further IC chip are arranged stacked on top of one another. These IC chips can be arranged congruently on top of one another or offset to one another, in particular if these chips have the same size when viewed from above. If these chips have different sizes when viewed from above, the smaller one of said IC chips is preferably located completely within the larger one of said IC chips when viewed from above.

According to at least one embodiment, the at least one cavity and the at least one further cavity face each other. This means that there is no material of the associated IC chips in places or over the entire surface between the cavities in question.

According to at least one embodiment, the at least one cavity and the at least one further cavity overlap when viewed from above. The cavities in question may be arranged congruently or offset relative to one another. Viewed from above, the cavities in question may be of the same size or of different sizes.

According to at least one embodiment, a plurality of soldering surfaces is provided on the top side and on the other top side. Soldering surfaces assigned to one another are connected to one another by means of at least one solder. This allows a ball grid array, or BGA for short, to be formed. The IC chips are mechanically and optionally also electrically connected to each other by means of the soldering surfaces and the solder. The IC chips have corresponding conductor structures.

According to at least one embodiment, at least one of the soldering surfaces extends as a closed path completely along three sides of the at least one cavity and the associated at least one further cavity, seen in plan view of the top side. This means, for example, that the soldering surfaces in question surround the cavities in a U-shape. These soldering surfaces can run along edges of the cavities or along outer edges of the IC chips, as seen in plan view.

According to at least one embodiment, first electrical connection surfaces of the IC chip are arranged within the at least one cavity. The at least one optoelectronic semiconductor chip is attached to or on the first electrical connection surfaces. For example, the optoelectronic semiconductor chip in question is soldered onto one of the first electrical connection surfaces and is electrically connected to one or more of the further first electrical connection surfaces via electrical connecting means, such as bonding wires.

According to at least one embodiment, the optoelectronic semiconductor device further comprises an electronics carrier. The electronics carrier is, for example, a circuit board, such as a printed circuit board, PCB for short, a metal core board or a ceramic board.

According to at least one embodiment, the IC chip has first electrical connection surfaces and is attached to the electronics carrier by means of the first electrical connection surfaces. The at least one optoelectronic semiconductor chip is attached to second electrical connection surfaces of the electronics carrier. Associated first electrical connection surfaces and second electrical connection surfaces are electrically short-circuited. This means that, for the intended application, there is no significant electrical resistance between the associated first and second electrical connection surfaces.

According to at least one embodiment, the at least one cavity is only open towards the top side of the IC chip. This means that, viewed from above, the at least one cavity is surrounded on all sides by the top side and/or by the silicon base body.

According to at least one embodiment, the at least one cavity is open towards the top side of the IC chip and towards exactly one side face of the IC chip. In other words, viewed from above on the top side, the at least one cavity is only partially surrounded laterally by the top side and/or by the silicon base body.

According to at least one embodiment, the at least one cavity widens continuously in the direction towards the top side. This means that the cavity becomes narrower with increasing depth. For example, the cavity is truncated pyramid-shaped.

According to at least one embodiment, during operation, radiation emission of the at least one optoelectronic semiconductor chip out of the at least one cavity takes place in parallel to the top side.

Alternatively, the radiation emission out of the at least one cavity takes place in a direction perpendicular to the top side.

According to at least one embodiment, the optoelectronic semiconductor device further comprises at least one cover. The cover partially or completely closes the at least one cavity.

According to at least one embodiment, the cover is transparent to radiation emitted by the at least one optoelectronic semiconductor chip during operation. The cover can be clear or milky opaque. It is possible that at least one optical filter material is added to the cover so that the cover is transparent, for example, only in part of the visible and/or near-infrared spectral range.

According to at least one embodiment, the cover and the IC chip are congruent when viewed from above or from the side. This means that the cover can completely cover the IC chip. The same applies to the at least one further IC chip.

According to at least one embodiment, the cover is L-shaped when viewed in cross-section. This means, for example, that the cover extends over the top side and one side face of the IC chip in question. Cross-sectionally perpendicular to the top side, [symbol] -shaped or [symbol] -shaped covers are also possible.

According to at least one embodiment, the at least one optoelectronic semiconductor chip is a laser diode chip. The at least one semiconductor chip in question may be an edge-emitting laser diode chip. It is also possible for the at least one semiconductor chip in question to be a vertical cavity surface emitting laser, or VCSEL for short. LED chips as volume emitters or surface emitters can also be used. An emission wavelength can be in the wavelength range from ultraviolet, UV, to infrared, IR.

In addition or as an alternative to the radiation-emitting optoelectronic semiconductor chips, radiation-receiving optoelectronic semiconductor chips can be used, such as photodiodes or light sensors.

In addition, a method for manufacturing an optoelectronic semiconductor device as described in connection with one or more of the above embodiments is provided. Features of the optoelectronic semiconductor device are therefore also disclosed for the method and vice versa.

In at least one embodiment, the method is used to manufacture a plurality of optoelectronic semiconductor devices. The method comprises the following steps, in particular in the order given:
providing a wafer composite including a plurality of the IC chips,
forming the cavities in the respective IC chips,
placing the optoelectronic semiconductor chips in the cavities, and
singulating the wafer composite into the optoelectronic semiconductor devices.

Further disclosed are data glasses comprising at least one optoelectronic semiconductor device as described in connection with one or more of the above embodiments. Features of the optoelectronic semiconductor device are therefore also disclosed for the data glasses and vice versa.

In at least one embodiment, the data glasses comprise
a frame,
at least one optoelectronic semiconductor device in the frame,
an imaging unit in the frame, which is arranged downstream of the at least one optoelectronic semiconductor device, and
an imaging element in the frame, which is arranged downstream of the imaging unit.

In the following, an optoelectronic semiconductor device described herein, a method described herein and data glasses described herein are explained in more detail with reference to the drawing by means of embodiment examples. Identical reference signs indicate identical elements in the individual figures. However, no references are shown to scale; rather, individual elements may be shown in exaggerated size for better understanding.

### BRIEF DESCRIPTION OF THE DRAWINGS

In the figures:

FIGS. 1 to 5 are schematic top views of method steps of an embodiment of a method for manufacturing optoelectronic semiconductor devices described herein,

FIG. 6 is a schematic sectional view of an embodiment of an optoelectronic semiconductor device described here,

FIGS. 7 and 8 are schematic top views of embodiments of optoelectronic semiconductor devices described herein,

FIG. 9 is a schematic sectional view of an embodiment of an optoelectronic semiconductor device described herein,

FIGS. 10 and 11 are schematic top views of IC chips for embodiments of optoelectronic semiconductor devices described herein,

FIGS. 12 to 14 are schematic sectional views of embodiments of optoelectronic semiconductor devices described herein,

FIGS. 15 to 20 are schematic top views of method steps of an embodiment of a method for manufacturing optoelectronic semiconductor devices described herein,

FIG. 21 is a schematic top view of an embodiment of an optoelectronic semiconductor device described herein,

FIG. 22 is a schematic sectional view of an embodiment of an optoelectronic semiconductor device described herein, and

FIG. 23 is a schematic sectional view of an embodiment of data glasses with optoelectronic semiconductor devices described here.

### DETAILED DESCRIPTION

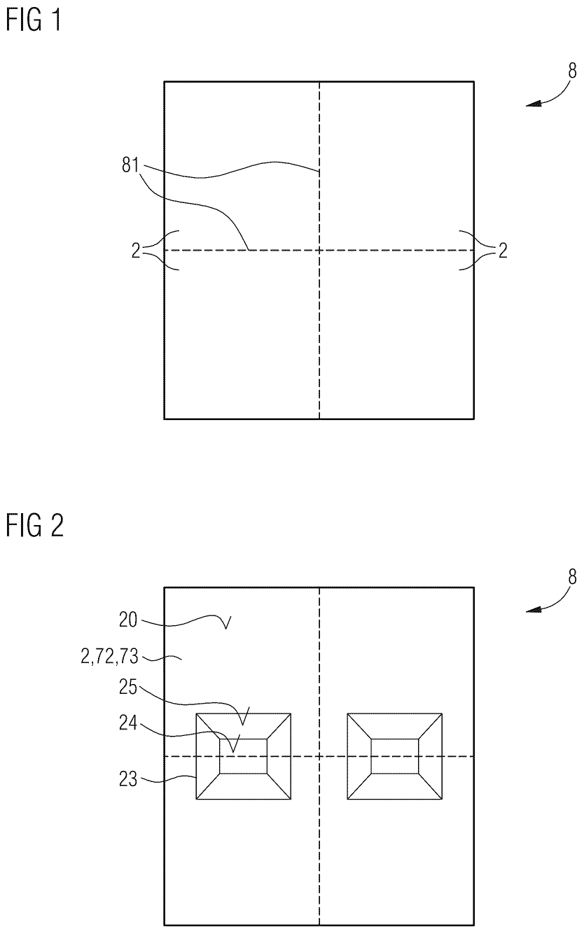

FIGS. 1 to 5 illustrate a manufacturing process for optoelectronic semiconductor devices 1. According to FIG. 1, a wafer composite 8 is provided. The wafer composite 8 comprises a plurality of IC chips 2; only two of the IC chips 2 are shown as examples. The IC chips 2 can all be identical in construction. There are separation lines 81 between adjacent IC chips 2. It is possible that the separation lines 81 on the wafer composite 8 itself are not directly visible to the outside; alternatively, there may be markings that identify the separation lines 81.

In the step shown in FIG. 2, cavities 23 are formed in the IC chips 2 from a top side 20 of the wafer composite 8. This is done in particular by etching, for example, with KOH. Corresponding masks or similar aids are not shown in FIG. 2 to simplify the illustration.

For example, there is exactly one cavity per IC chip 2. Still in the wafer composite 8, the associated cut-outs can extend over two adjacent IC chips 2. This means that the respective cut-out is divided by the associated separation line 81 into the two cavities 23 for the two IC chips 2 concerned. Thus, the cavities 23 extend from the top side 20 and extend to a lateral edge of the IC chips 2. Bottom surfaces 24 of the cavities 23 are oriented parallel to the top side 20, for example. Side walls 25 of the cavities 23 may extend oblique to the top side 20. The cut-outs and the cavities 23 can thus have a truncated cone-shape.

The individual IC chips 2, which are still integrally connected to each other in the wafer composite 8, have, for example, a large number of switching elements, such as transistors 72. Optionally, electrical resistors 73 can also be included in the IC chips 2. The wafer composite 8 is, for example, a silicon-based wafer that has been processed so that the switching elements and optionally the resistors are generated. This is not shown in detail in the figures.

For example, a width and/or a length of the IC chips 2 is at least 1 mm or at least 2 mm. Alternatively or additionally, the width and/or length is at most 1 cm or at most 4 mm. A thickness of the IC chips 2 is, for example, at least 0.2 mm or at least 0.3 mm and/or at most 2 mm or at most 1 mm. A depth of the cavities 23 is, for example, at least 20% or at least 30% and/or at most 80% or at most 70% of the thickness of the IC chips 2. Alternatively or additionally, the depth of the cavities 23 is at least 0.25 mm or at least 0.1 mm and/or at most 0.5 mm.

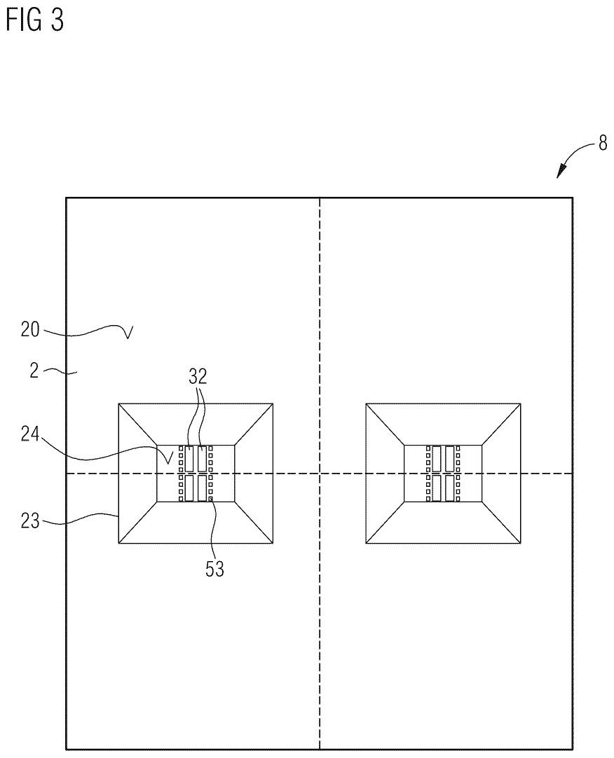

FIG. 3 illustrates that a plurality of first electrical connection surfaces 53 are located in each of the cavities 23 on the bottom surfaces 24. These first electrical connection surfaces 53 are either exposed by the generation of the cavities 23, or are generated on the bottom surfaces 24 in a separate step after the cavities 23 have been generated. It is possible that several types of first electrical connection surfaces 53 are present, for example, small first connection surfaces and large first connection surfaces.

Furthermore, FIG. 3 shows that a laser diode chip 32 is applied to each of the large first connection surfaces. The small first connection surfaces are configured for bonding wires, not shown in FIG. 3. This means that the laser diode chips 32 of neighboring IC chips 2 are directly opposite each other in the cut-outs. Alternatively, the laser diode chips 32 can also be applied and electrically contacted only after singulating, see FIG. 5 below.

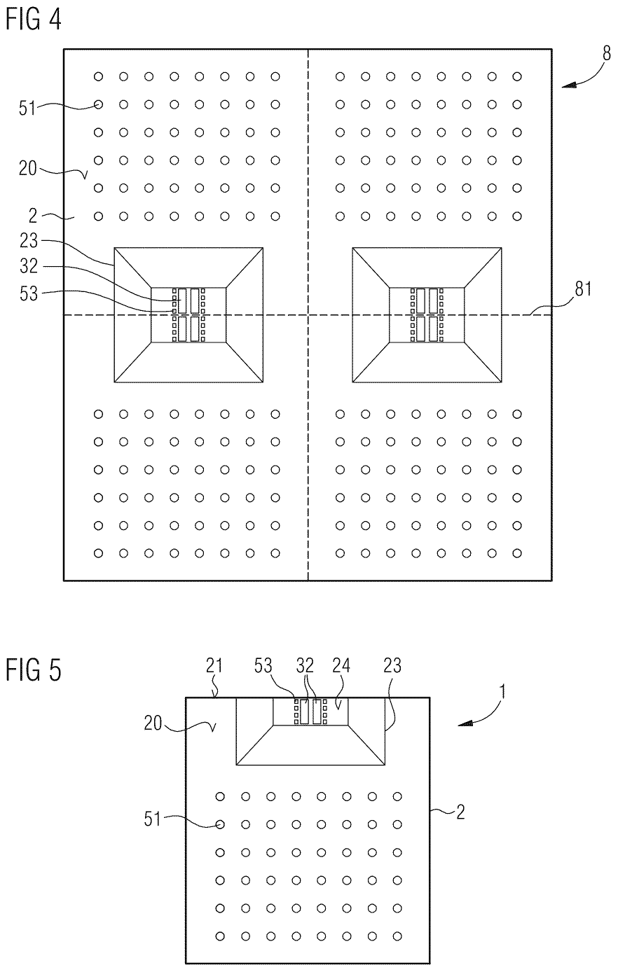

In the optional process step of FIG. 4, it is shown that a plurality of soldering surfaces 51 are generated on the remaining areas of the top side 20. The soldering surfaces 51 are, for example, metallizations. According to FIG. 4, the soldering surfaces 51 are shaped like dots. The soldering surfaces 51 are designed in particular for a BGA. The IC chips 2 can be electrically contacted externally and mechanically fastened via the soldering surfaces 51. Such soldering surfaces 51 can be provided both on the top side 20 and on a main side opposite the top side 20 or also only on the opposite main side, unlike what is shown in FIG. 4.

In the step shown in FIG. 5, the optoelectronic semiconductor devices 1 are singulated along the separation lines 81, see also FIG. 1, for example, by means of sawing, grinding, etching and/or laser irradiation. This forms side faces 21. The finished optoelectronic semiconductor devices 1 thus each comprise an IC chip 2 and one or more of the laser diode chips 32, which are, for example, edge-emitting lasers. The laser diode chips 32 can emit in different spectral ranges or alternatively be identical in construction.

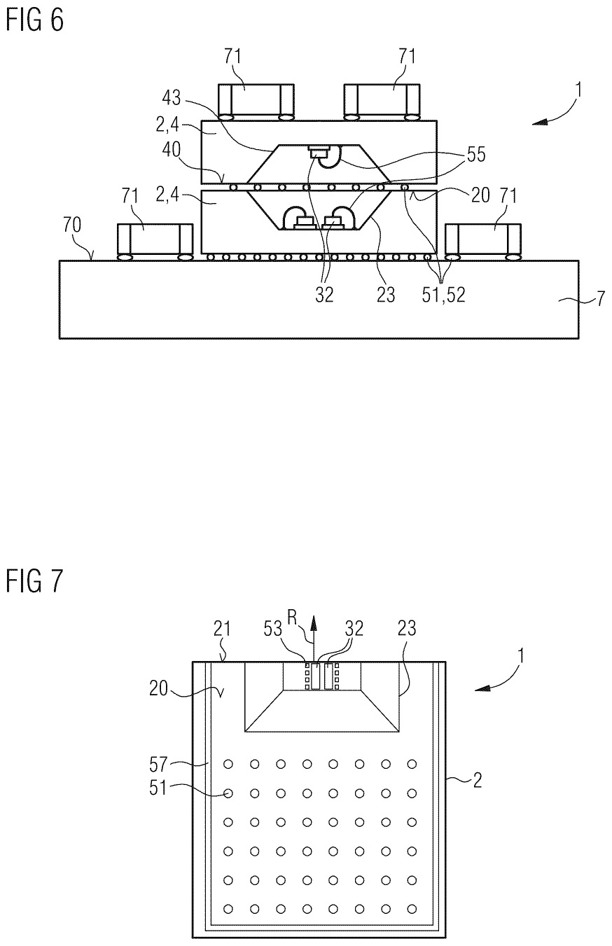

FIG. 6 shows an example of an optoelectronic semiconductor device 1. The optoelectronic semiconductor device 1 comprises the IC chip 2 with the two laser diode chips 32, as resulting from the process step of FIG. 5.

As an option, it is shown that this IC chip 2 is attached to an electronics carrier 7 by means of a solder 52 and the soldering surfaces 51. The electronics carrier 7 is, for example, a ceramic substrate that can contain conductor tracks for operating the optoelectronic semiconductor device 1. The cavity 23 and a further cavity 43 of a further IC chip 4 face each other so that, viewed in cross-section, a polygonal opening, such as a hexagonal hole, can be formed through the cavities 23 and 43 as a whole. The laser diode chips 32 emit in a direction parallel to the top side 20.

As a further option, FIG. 6 shows that the further IC chip 4 is arranged stacked on the IC chips 2, for example, stacked congruently, as seen in plan view of a carrier top side 70 of the electronics carrier 7. The same applies to the further IC chip 4 as described above for the IC chip 2, and vice versa.

It is also possible, as shown in FIG. 6, for capacitors 71 to be present. The capacitors 71 can be used to realize short switching times of the laser diode chips 32. Electrical lines between the capacitors 71 and the laser diode chips 32 are preferably as short as possible. The capacitors 71 can be mounted on the carrier top side 70 and/or on a side of the further IC chip 4 facing away from the electronics carrier 7.

Thus, in the optoelectronic semiconductor device 1 shown in FIG. 6, two IC chips 2, 4 are stacked on top of each other. Prior to a stacking process, the laser diode chips 32 are inserted into the cavities 23, 43 of the IC chips 2, 4, for example, by means of AuSn soldering and contacting by means of bonding wires 55. A mechanical and electrical connection of the IC chips 2, 4 is produced by a soldering process, in particular by means of a BGA. The upper IC chip 4 and the capacitors 71 attached to the upper IC chip 4 are contacted to the lower IC chip 2, to the electronics carrier 7 and to the laser diode chips 32, for example, via through-silicon vias or TSV for short.

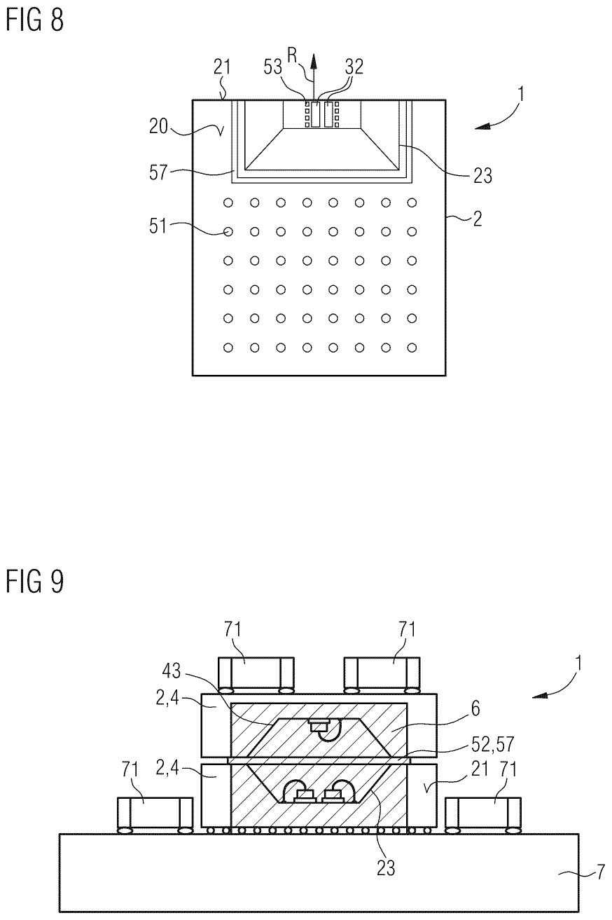

FIGS. 7 and 8 show further examples of optoelectronic semiconductor devices 1. In each of these examples, there is a soldering surface 57 which extends as a closed track. Such a soldering surface 57 can be located on the top side 20 and/or on the opposite main side. The soldering surface 57 completely surrounds the cavity 23 along three sides. The soldering surface 57 may extend to the side face of the IC chip 2, where a radiation R generated by the laser diode chips 32 is emitted during operation. The soldering surface 57 is thus U-shaped when viewed from above.

According to FIG. 7, the soldering surface 57 extends along and close to an outer edge of the IC chip 2, seen in plan view. In contrast, the soldering surface 57 in FIG. 8 is located along and close to an edge of the cavity 23. Close means, for example, a distance of at most 0.1 mm or of at most 0.2 mm and/or a distance of at most 5% or of at most 10% of a length of a diagonal of the top side 20.

In all other respects, the comments on FIGS. 1 to 6 apply in the same way to FIGS. 7 and 8, and vice versa.

In the example shown in FIG. 9, as in FIG. 6, the IC chips 2, 4 are arranged stacked on top of each other. A cover 6 is attached to the side faces 21 of the IC chips 2, 4, where the cavities 23, 43 are exposed and where the radiation R is emitted. The cover 6 is made of glass or sapphire, for example. The cover 6 is permeable to the radiation R. The cover 6 is used in particular in combination with the soldering surface 57 according to FIG. 7 or according to FIG. 8.

For example, the cover 6 is glued or soldered onto the IC chips 2, 4, either by means of a metallic solder or also by means of a glass solder. With such a cover 6, the cavities 23, 43 can be hermetically sealed.

Thus, in addition to the soldering surfaces 51 for the BGA, the IC chips 2, 4 have the U-shaped soldering surface 57. After the soldering process, this structure 57 generates an arrangement that is only open on one side around the complete IC chips 2, 4, see FIG. 7, or only around the cavities 23, 43, see FIG. 8. After stacking the IC chips 2, 4, the cover 6 can be applied to the front side of the IC chips 2, 4 in order to hermetically seal the laser cavities 23, 43. Any misalignment of the IC chips 2, 4 relative to each other due to assembly tolerances can optionally be eliminated by grinding, so that the cover 6 can then sit completely flush.

In all other respects, the explanations in FIGS. 1 to 8 apply in the same way to FIG. 9, and vice versa.

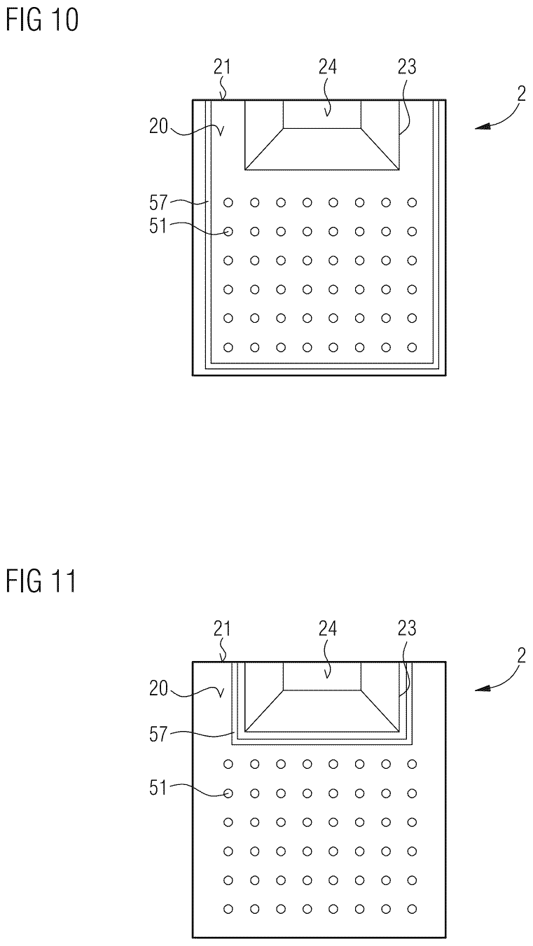

In the examples of FIGS. 10 and 11, there are no electrical connection surfaces on the bottom surface 24.

In all other respects, the comments on FIGS. 7 and 8 apply in the same way to FIGS. 10 and 11.

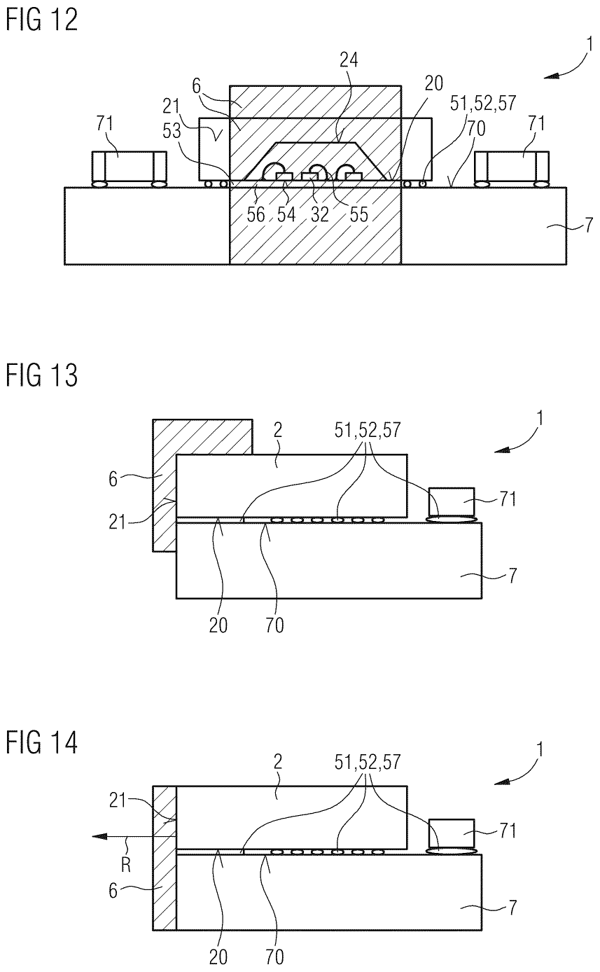

In the optoelectronic semiconductor device 1, as shown in FIG. 12, the IC chips 2 of FIG. 10 or 11 can be used. For this purpose, the electronics carrier 7 has several electrical conductor tracks 56 and second electrical connection surfaces 54 on the carrier top side 70. The electrical conductor tracks 56 are short-circuited to the first electrical connection surfaces 53 of the IC chip 2. The first electrical connection surfaces 53 are located on the top side 20 and thus outside the cavity 23.

The laser diode chips 32 are attached to the larger of the second electrical connection surfaces 54 and optionally connected to the smaller of the second electrical connection surfaces 54 by means of the bonding wires 55. There may be a one-to-one assignment between the first and second electrical connection surfaces 53, 54. Alternatively, all of the smaller second electrical connection surfaces 54 of a particular laser diode chip 32 may be associated with a single one of the first electrical connection surfaces 53.

Optionally, the cover 6 can also be present. The cover 6 is, for example, L-shaped when viewed in cross-section, see FIGS. 12 and 13, or designed as a flat plate, see FIG. 14.

It is also possible in the design of FIG. 12 that a further IC chip 4 is present, analogous to FIG. 9. In this case, the further IC chip 4 can be designed according to FIG. 10 or 11, and the IC chip 2 assumes the role of the electronics carrier 7 for the further IC chip 4. Furthermore, it is possible that two further IC chips 4 are present stacked on top of each other, which are stacked on the IC chip 2 of FIG. 12 analogous to the IC chips 2, 4 of FIG. 9. In the latter case, it is possible that each of the IC chips 2, 4 then has exactly one of the laser diode chips 32 and an RGB module is realized in total.

Thus, in the variant shown in FIGS. 12 to 14, the laser diode chips 32 are mounted on the electronics carrier 7. The IC chip 2 is then soldered onto the electronics carrier 7. In order to hermetically seal the cavity 23, the cover 6 can then be applied, either as a flat window or as an L-shaped cover, which allows alternative mounting.

In all other respects, the explanations in FIGS. 1 to 11 apply in the same way to FIGS. 12 to 14, and vice versa.

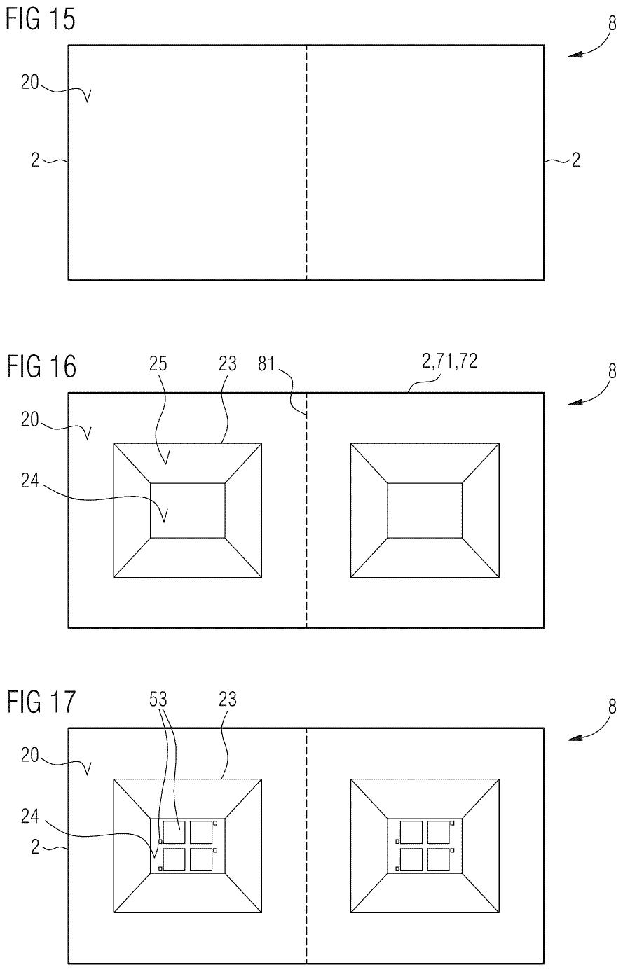

FIGS. 15 to 20 describe a further manufacturing process. Analogous to FIG. 1, the wafer composite 8 is provided according to FIG. 15.

FIG. 16 illustrates that a cavity 23 is formed in each of the IC chips 2. In contrast to FIG. 2, however, the cavities 23 are located in the center of the IC chips 2 and not at the separation lines 81. Thus, the cavities 23 extend exclusively from the top side 20. The cavities 23 are, for example, truncated pyramid-shaped. The bottom surface 24 is square or rectangular, for example.

According to FIG. 17, the first electrical connection surfaces 53 are generated. Contact points to corresponding electrically conducting structures of the IC chips 2 are not drawn in FIG. 17. The first electrical connection surfaces 53 can comprise large connection surfaces and small connection surfaces.

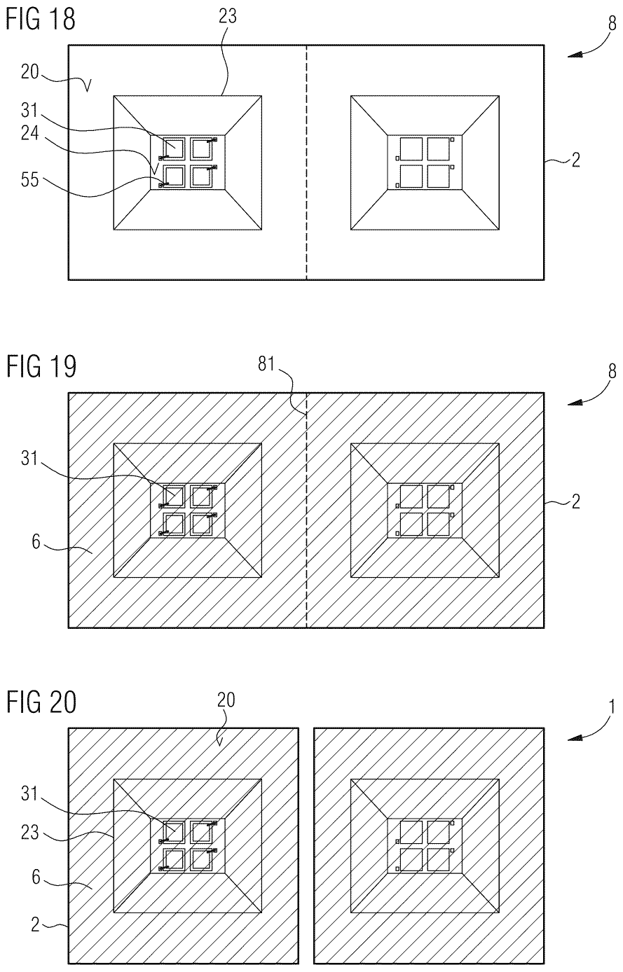

In the process step of FIG. 18, light emitting diode chips 31 are placed on the large connection surfaces and contacted with the small connection surfaces by means of the bonding wires 55. Alternatively, just as in all other examples, flip chips can also be used in which all electrical contact areas are located on a single main side, whereby this main side can face the bottom surface 24 or also the carrier top side 70. Especially in the case of flip chips, a mounting of the optoelectronic semiconductor chips free of bonding wires is possible.

For example, red, green and blue emitting light-emitting diode chips 31 are mounted to create an RGB module. As an alternative or in addition to light-emitting diode chips 31, VCSEL chips and therefore lasers can also be mounted. Such VCSELs emit near-infrared radiation, for example. Alternatively or additionally, photodiodes can be installed.

In the optional step shown in FIG. 19, the cover 6 is preferably still applied in the wafer composite. The one-piece cover 6 completely covers all cavities 23. As an alternative to a one-piece cover 6, a plurality of individual covers 6 can also be placed. The cover is mounted, for example, by adhesion, laser welding or anodic bonding.

According to FIG. 20, the wafer composite 8 is singulated to form the optoelectronic semiconductor devices 1, analogous to FIG. 5.

In all other respects, the explanations relating to FIGS. 1 to 14 apply in the same way to FIGS. 15 to 20, and vice versa.

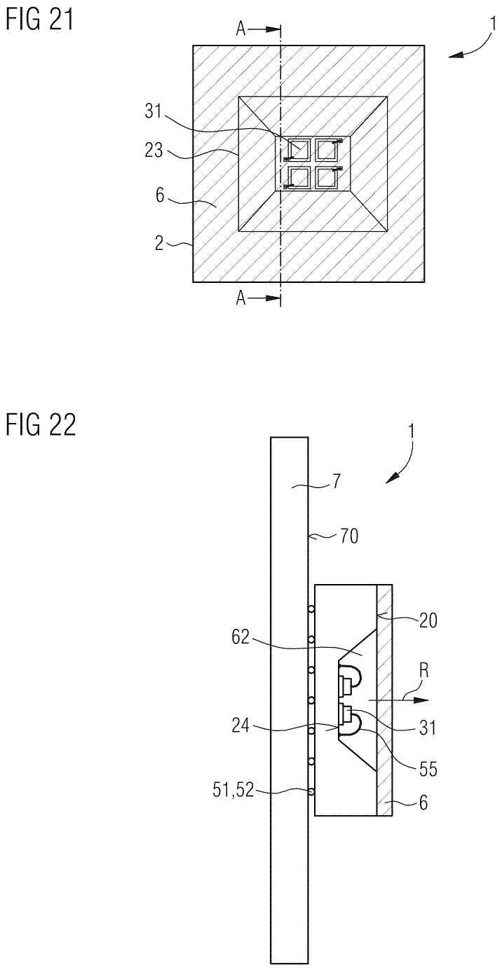

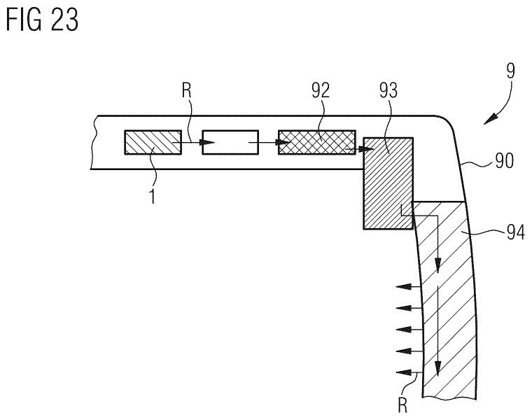

In FIGS. 21 and 22, the semiconductor device 1 produced using the method of FIGS. 15 to 20 is drawn in more detail, with FIG. 22 being a sectional view along line A-A of FIG. 21. The optional electronics carrier 7 is present as an additional component in FIG. 22.

The connection to the electronics carrier 7 is again made by using a BGA, for example. Optionally, analogous to FIG. 9 or 12, capacitors 71 may be present, not shown in FIGS. 21 and 22. The radiation R is emitted vertically or essentially vertically to the top side 20 through the cover 6.

The cover 6 may be clear, in particular for the radiation R. Furthermore, the cover 6 may include an optical filter material, for example, to prevent or attenuate the penetration of unwanted radiation from outside into the cavity 23.

In FIG. 22, the cover 6 is shown as a plane-parallel plate. Alternatively, the cover 6 can also be lens-shaped, for example in the form of a converging lens such as a Fresnel lens.

Alternatively or in addition to the cover 6, which is placed on the cavity 23 and does not extend into the cavity 23, for example, a potting 62 may be present in the cavity 23. Such a potting 62 is, for example, made of an epoxy, a silicone, a siloxane or mixtures thereof. Such a potting 62 may also include an optical filter. The cavity 23 may be completely, alternatively only partially, filled with the potting 62. If there is no cover 6, but only the potting 62, the potting 62 can have an optically effective shape, such as a lens shape.

In all other respects, the explanations relating to FIGS. 1 to 20 apply in the same way to FIGS. 21 and 22, and vice versa.

FIG. 23 shows one half of data glasses 9; the second, undrawn half of the data glasses 9 can be symmetrical to the first half. The data glasses 9 are intended, for example, for applications in the field of virtual reality, VR, or augmented reality, AR. Optoelectronic semiconductor devices 1, as illustrated in connection with FIGS. 1 to 22, are used as the light source in the data glasses 6. The optoelectronic semiconductor devices 1 are integrated in a frame 90, for example in temples, of the data glasses 9.

For example, the optoelectronic semiconductor devices 1 are each followed by an optical element 91. The optical element 91 can be used to adjust optical properties of the radiation R emitted by the optoelectronic semiconductor devices 1, such as a divergence and/or direction. Furthermore, an imaging unit 92 can be connected downstream, such as a micro-electromechanical element, MEMS, or a liquid crystal on silicon, LCoS. In addition, a relay optics 93 may optionally be present between the imaging unit 92 and an imaging element 94. The imaging element 94 is, for example, a projection screen or a holographic mirror.

In all other respects, the comments on FIGS. 1 to 22 apply in the same way to FIG. 23, and vice versa.

The components shown in the figures preferably follow one another in the order indicated, in particular directly one after the other, unless otherwise described. Components not touching each other in the figures preferably have a distance between them. If lines are drawn parallel to each other, the associated surfaces are preferably also aligned parallel to each other. In addition, the relative positions of the drawn components to each other are shown correctly in the figures, unless otherwise specified.

The invention described herein is not limited by the description based on the embodiments. Rather, the invention includes any new feature as well as any combination of features, which includes in particular any combination of features in the patent claims, even if this feature or combination itself is not explicitly stated in the patent claims or embodiments.

1. An optoelectronic semiconductor device comprising:
an IC chip based on a semiconductor material and having a top side, and
at least one optoelectronic semiconductor chip,
wherein
the at least one optoelectronic semiconductor chip is completely mounted in at least one cavity of the IC chip,
the at least one cavity extends from the top side,
the at least one optoelectronic semiconductor chip is electrically connected directly to the IC chip, and
the at least one cavity is open towards the top side of the IC chip and towards exactly one side face of the IC chip.

2. The optoelectronic semiconductor device according to claim 1, comprising a plurality of said optoelectronic semiconductor chips, wherein the IC chip comprises a silicon base body and the at least one cavity is located in the silicon base body.

3. The optoelectronic semiconductor device according to claim 2, further comprising at least one further IC chip having at least one further cavity and having a further top side, wherein one of the optoelectronic semiconductor chips is completely located in the at least one further cavity.

4. The optoelectronic semiconductor device according to claim 3,
wherein the IC chip and the at least one further IC chip are arranged stacked one above the other.

5. The optoelectronic semiconductor device according to claim 3, wherein a plurality of soldering surfaces are present on the top side and on the further top side, the soldering surfaces are connected to one another by means of at least one solder.

6. The optoelectronic semiconductor device according to claim 5, wherein at least one of the soldering surfaces extends as a closed path completely along three sides of the at least one cavity and of the at least one further cavity, seen in plan view of the top side.

7. The optoelectronic semiconductor device according to claim 1, wherein first electrical connection surfaces of the IC chip are arranged within the at least one cavity, the at least one optoelectronic semiconductor chip is mounted on the first electrical connection surfaces.

8. The optoelectronic semiconductor device according to claim 1, further comprising an electronics carrier, wherein
the IC chip has first electrical connection surfaces and is attached to the electronics carrier by means of the first electrical connection surfaces,
the at least one optoelectronic semiconductor chip is mounted on second electrical connection surfaces of the electronics carrier, and
ones of the first electrical connection surfaces and second electrical connection surfaces assigned to one another are short-circuited.

9. The optoelectronic semiconductor device according to claim 1, wherein the at least one cavity widens continuously in a direction towards the top side.

10. The optoelectronic semiconductor device according to claim 2, wherein, in operation, radiation emission of the at least one optoelectronic semiconductor chip takes place parallel to the top side and out of the at least one cavity.

11. The optoelectronic semiconductor device according to claim 1, further comprising a cover, wherein the cover closes the at least one cavity.

12. The optoelectronic semiconductor device according to claim 11, wherein the cover and the IC chip are congruent, seen in plan view.

13. The optoelectronic semiconductor device according to claim 1, wherein the at least one optoelectronic semiconductor chip is a laser diode chip.

14. A manufacturing method by which a plurality of optoelectronic semiconductor devices according to claim 1 are manufactured, the manufacturing method comprising:
providing a wafer composite including a plurality of the IC chips,
forming the cavities in the respective IC chips,
mounting the optoelectronic semiconductor chips in the cavities, and
singulating the wafer composite to form the plurality of optoelectronic semiconductor devices.

15. Data glasses comprising:
a frame,
at least one optoelectronic semiconductor device according to claim 1 in the frame,
an imaging unit in the frame, the imaging unit is arranged downstream of the at least one optoelectronic semiconductor device, and
an imaging element in the frame, the imaging element is arranged downstream of the imaging unit.

16. The optoelectronic semiconductor device according to claim 3, wherein the at least one cavity and the at least one further cavity face each other and at least partially overlap, seen in plan view of the top side.

17. The optoelectronic semiconductor device according to claim 11, wherein the cover is permeable to radiation emitted by the at least one optoelectronic semiconductor chip in operation.

18. The optoelectronic semiconductor device according to claim 11, wherein the cover is L-shaped, seen in cross-section.
